(19) United States
(12) Patent Application Publication
(10) Pub. No.: US 2007/0223300 A1
(43) Pub. Date: Sep. 27, 2007

(54) PORTABLE ELECTRONIC APPARATUS WITH A POWER SAVING FUNCTION AND METHOD

(75) Inventors: Wen-Chuan Lian, Shenzhen (CN); Hua-Dong Cheng, Shenzhen (CN); Duo Liu, Shenzhen (CN); Kuan-Hong Hsieh, Shenzhen (CN)

Correspondence Address: NORTH AMERICA INTELLECTUAL PROPERTY CORPORATION, P.O. BOX 506, MERRIFIELD, VA, 22116, US

(73) Assignee: HON HAI PRECISION INDUSTRY CO., LTD., Taipei Hsien (TW)

(21) Appl. No.: 11/617,699

(22) Filed: Dec. 28, 2006

(30) Foreign Application Priority Data
Mar. 21, 2006 (CN) 200610034597.7

(51) Int. Cl. G11C 5/14

(52) U.S. Cl. 365/227

(57) ABSTRACT

A portable electronic apparatus with a power saving function is provided. A preferred embodiment of the apparatus includes a first data storage (11), a temp data storage (12), a power unit (14), a power control unit (13), and a CPU (15). The CPU is for sending a control instruction to the power control unit to control the power control unit to supply power to the first data storage when receiving a read or a write command, implementing a read process of reading data from the first data storage to the second data storage, or implementing a write process of writing data from the second data storage to the first data storage in accordance with the received read or write command, and sending a control instruction to control the power control unit to cut off the power supply of the first data storage after the read or write process is implemented.

### BACKGROUND OF THE INVENTION

1. Field of the Invention

The present invention relates generally to a portable electronic apparatus with a power saving function and a method.

2. Description of Related Art

With the development of electronic technology, various battery-powered portable electronic apparatuses such as handsets, PDAs (Personal digital assistants), MP3s, and e-books, has brought convenience to people. The portable electronic apparatuses mainly uses a limited battery that may quickly run out of energy, and the battery of the portable electronic apparatus needs to be raised or replaced frequently to replenish power. Otherwise, the portable electronic apparatuses cannot work.

Many solutions are brought out to reduce the power consumption of the portable electronic apparatuses, thus to prolong service times per charge of the batteries of the portable electronic apparatuses. Those solutions are generally adopts a “standby state” or a “sleep state” for a portable electronic apparatus. In the “standby state” or the “sleep state” the power supply to the portable electronic apparatus is reduced, thus reducing power consumed of the portable electronic apparatus. However, even through the portable electronic apparatus is in the “standby state” or “sleep state” and the nonvolatile data storage for storing commonly used data of the portable electronic apparatus is not used, the nonvolatile data storage is still powered on and consumes a lot electricity power.

Therefore, What is still needed is a portable electronic apparatus and method which can further save power.

### SUMMARY OF THE INVENTION

A portable electronic apparatus with a power saving function is provided. A preferred embodiment of the apparatus includes a first data storage, a second data storage, a power unit, a power control unit, and a CPU. The first data storage is for storing commonly used electronic data of the apparatus. The second data storage is for temporarily storing data read from the first data storage. The power unit is for supplying power to the first data storage. The power control unit interposed between the first data storage and the power unit is for controlling power supply of the first data storage. The CPU is for signaling the power control unit to supply power to the first data storage when receiving a read or a write command, invoking a read process of reading data from the first data storage to the second data storage, or invoking a write process of writing data from the second data storage to the first data storage in accordance with the received read or write command, and signaling the power control unit to cut off the power supply of the first data storage after the read or write process is implemented.

A method for implementing a power saving function of the portable electronic apparatus is provided. The method includes the step of: receiving a read or write command; signaling a power control unit to supply power to the first data storage; invoking a read process of reading data from the first data storage to the second data storage, or invoking a write process of writing data from the second data storage to the first data storage; signaling the power control unit to cut off the power supply of the first data storage after the read or write process is implemented.

Other advantages and novel features will be drawn from the following detailed description of the preferred embodiment with reference to the attached drawings, in which:

### BRIEF DESCRIPTION OF THE DRAWINGS

FIG. 1 is an exemplary hardware infrastructure diagram of a portable electronic apparatus with a power saving function of a preferred embodiment of the present invention; and

FIG. 2 is a flow chart for implementing a power saving function of the portable electronic apparatus of FIG. 1.

### DETAILED DESCRIPTION OF THE INVENTION

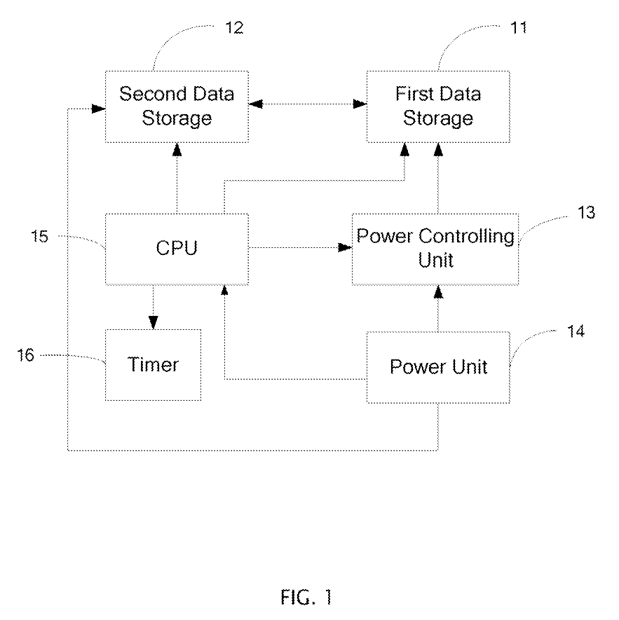

FIG. 1 is an exemplary hardware infrastructure diagram of a portable electronic apparatus with a power saving function (hereinafter “the apparatus”) of a preferred embodiment of the present invention. The apparatus includes a first data storage 11, a second data storage 12, a power control unit 13, a power unit 14, a CPU (Central Processing Unit) 15, and a timer 16.

The first data storage 11 is a nonvolatile data storage for storing commonly used electronic data of the apparatus. The second data storage 12 is a volatile storage such as a memory, for temporarily storing temporary read data fetched from the first data storage 11 or temporary unwritten data received from external apparatus such as a wired/wireless network or an external device.

The power unit 14 is for supplying power to power consuming components of the apparatus. In the preferred embodiment, the power unit 14 supplies power directly to the temp data storage 12, the power control unit 13, and the CPU 15. The power control unit 13 is interposed between the first data storage 11 and the power unit 14 and used for controlling the power supply of the first data storage according to a control instruction produced and transmitted by the CPU 15.

In the preferred embodiment, when the first data storage 11 is not in use, the power supply of the first data storage 11 is cut off by the CPU 15 to change a state of the first data storage 11 to be in a disabled state. The temporary unwritten data that is to be stored in the first storage device is temporarily stored in the temp data storage 12. When the CPU 15 receives a read command or a write command, the CPU 15 signals the power control unit 13 to supply power to the first data storage 11, thus changing the state of the first data storage 11 to be in an enabled state.

Generally, the read commands and the write commands are generated according to user's inputs. The read commands instructs the CPU 15 to invoke a read process that reads data from the first data storage 11 to the second data storage 12 and the write commands instructs the CPU 15 to invoke a write process that writes data from the second data storage 12 to the first data storage 11. The CPU 15 may also be configured to automatically invoke the write process at a predetermined time interval or when a data capacity of the second data storage 12 is full. According to the preferred embodiment, the CPU 15 may further be configured to invoke the write process according to the read commands, i.e., The CPU 15 may be configured to invoke the write process first before invoking the read process when the read command is received.

After implementing the read process and/or the write process, the CPU 15 starts the timer 16 to clock an elapsed time when the CPU 15 does not receive either of the read commands and write commands. When the elapsed time reaches a predetermined time, the CPU 15 signals the power control unit 13 to cut off the power supply to the first data storage 11, thus changing the state of the first data storage 11 to be the disabled state.

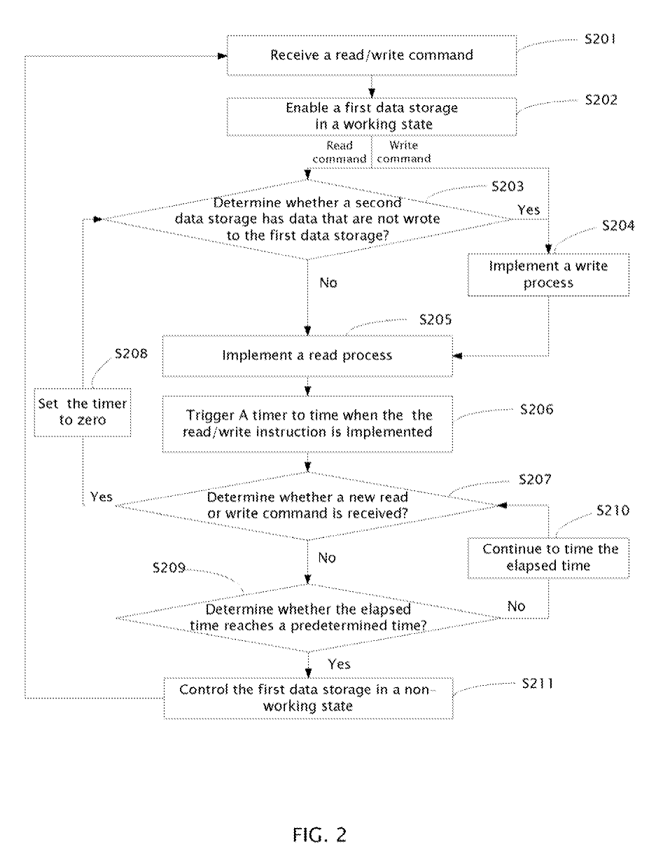

FIG. 2 is a flow chart for implementing a power saving function of the portable electronic apparatus of FIG. 1.

In step S201, the CPU 15 receives the read command or the write command.

In step S202, the CPU 15 signals the power control unit to supply power the first data storage 11, thus changing the state of the first data storage 11 to be in the enabled state.

If the CPU 15 receives the read command in step s202, in step 203 the CPU 15 detects whether the second data storage contains the temporary unwritten data.

If the CPU 15 detects the temporary unwritten data in the second storage in step S203, in step S204, the CPU 15 invokes the write process and writes the temporary unwritten data from the second data storage 12 to the first data storage 11.

Then in step S205, the CPU 15 invokes the read process and fetches electronic data from the first data storage 11 to the second data storage 12. If the second storage does not contain the temporary unwritten data in step S203, the procedure goes directly to step S205 described in the forgoing.

In step S206, the CPU 15 starts the timer 16 to time the elapsed time after the read process that the CPU 15 does not receive either of the read command and the write command

In step S207, the CPU 15 detects whether a new read command or a new write command is received.

If the CPU 15 receives the new read command or the new write command in step S207, in step S208, the CPU 15 resets the timer 16 and then the procedure returns to the step S203.

If the CPU 15 does not receives either of the new read command and the write command in step S207, in step S209, the CPU 15 detects whether the elapsed time reaches the predetermined time. If the elapsed time has not reached the predetermined time, the timer 16 continues to time the elapsed time in step S210 and the procedure returns to step S207 described above.

If the elapsed time reaches the predetermined time, in step S211, the CPU 15 signals the power control unit 13, to cut off the power supply to the first data storage 11, thus changing the state of the first data storage 11 to be the disabled state.

The procedure then returns to step S201 and reiterates until the apparatus is powered off.

Although the present invention has been specifically described on the basis of a preferred embodiment, the invention is not to be construed as being limited thereto. Various changes or modifications may be made to the embodiment without departing from the scope and spirit of the invention.

What is claimed is:

1. A portable electronic apparatus with a power saving function, comprising:
a first data storage for storing commonly used electronic data of the apparatus;
a second data storage for temporarily storing data read from the first data storage;
a power unit for supplying power to the first data storage;
a power control unit interposed between the first data storage and the power unit for controlling power supply of the first data storage; and
a CPU for signaling the power control unit to supply power the first data storage when receiving a read or a write command, invoking a read process of reading data from the first data storage to the second data storage, or invoking a write process of writing data from the second data storage to the first data storage in accordance with the received read or write command, and signaling the power control unit to cut off the power supply of the first data storage after the read or write process is implemented.

2. The apparatus as described in claim 1, wherein the first data storage is a nonvolatile data storage.

3. The apparatus as described in claim 1, wherein the second data storage is a volatile data storage.

4. The apparatus as described in claim 1, the CPU is further for executing the write process first before the read process when the read command is received.

5. The apparatus as described in claim 1, wherein further comprises a timer, the CPU starts the timer to clock an elapsed time when the CPU does not receive any of the read commands and write commands, and the CPU signals the power control unit to cut off the power supply to the first data storage 11 when the elapsed time reaches a predetermined time.

6. A method for implementing a power saving function of the portable electronic apparatus, comprising:
receiving a read or write command;
signaling a power control unit to supply power to the first data storage;
invoking a read process of reading data from the first data storage to the second data storage, or invoking a write process of writing data from the second data storage to the first data storage;
signaling the power control unit to cut off the power supply of the first data storage after the read or write process is implemented.

7. The method as described in claim 6, further comprises the step of executing the write process first before the read process when the read command is received.

8. The method as described in claim 6, further comprises the step of automatically invoke the write process at a predetermined time interval.

9. The method as described in claim 6, further comprises the step of automatically invoke the write process when the second data storage is full.

10. The method as described in claim 6, further comprises the step of timing an elapsed time during which no read and write commands is received, and signaling the power control unit to cut off the power supply to the first data storage when the elapsed time reaches a predetermined time.
